(19) United States
(12) Patent Application Publication
(10) Pub. No.: US 2008/0129377 A1
(43) Pub. Date: Jun. 5, 2008

(54) Voltage regulator with current sink for diverting external current and digital amplifier including the same

(76) Inventors: Seung-Bin You, Seongnam-si (KR); Chun-Kyun Seok, Seoul (KR); Yong-Jin Cho, Bupyeong-Gu (KR)

Correspondence Address: LAW OFFICE OF MONICA H CHOI, P O BOX 3424, DUBLIN, OH, 430160204, US

(21) Appl. No.: 11/998,216

(22) Filed: Nov. 29, 2007

(30) Foreign Application Priority Data
Nov. 30, 2006 (KR) 2006-119484

(51) Int. Cl. H03F 3/38; G05F 1/44

(52) U.S. Cl. 330/10; 323/234

(57) ABSTRACT

A voltage regulator includes a voltage driving circuit and a current sinking unit. The voltage driving circuit is controlled to maintain an output signal at an output node. The current sinking unit is coupled to the output node for generating a sinking current for diverting an external current to the output node. An error amplifier generates a control signal from the output signal and a reference signal. The voltage driving circuit and the current sinking unit are controlled according to such a control signal.

### BACKGROUND OF THE INVENTION

This application claims priority under 35 USC §119 to Korean Patent Application No. 2006-119484 filed on Nov. 30, 2006 in the Korean Intellectual Property Office, the disclosure of which is incorporated herein in its entirety by reference.

1. Field of the Invention

The present invention relates generally to power supplies, and more particularly, to a voltage regulator with a current sink for diverting an external current such as for use in a digital amplifier.

2. Background of the Invention

Typically a circuit performing a particular function and a power supply circuit for providing power to the circuit are formed in respective semiconductor chips that are integrated on one or more printed circuit boards (PCBs). The integrated semiconductor chips are electrically connected to each other through bonding wires or printed wires on the PCB.

The power supply circuit is desired to supply stable power to another circuit regardless of an impedance variation of wiring between the power supply circuit and the other circuit. In particular, a digital amplifier with switching for amplifying a received signal has increased noise such as third harmonic distortion (THD) that degrades performance if power provided to switching elements is varied.

A voltage regulator provides stable power regardless of output impedance. In particular, a voltage regulator that operates even when a difference between an input voltage and an output voltage is relatively small is referred to as a low drop out (LDO) regulator. A LDO regulator having a small difference between input and output voltages is disclosed in Korean Patent Application Laid-Open Publication No. 2004-30308.

FIG. 1 is a circuit diagram of a conventional voltage regulator 100 according to the prior art. Referring to FIG. 1, the voltage regulator 100 includes an error amplifier 110, a voltage division circuit 120, and a voltage driving circuit 130. The error amplifier 110 amplifies a difference between a reference voltage VREF and a feedback voltage VFB to generate a control signal CVO. The voltage division circuit 120 generates the feedback voltage VFB by resistive-dividing an output voltage VO at an output node N1 with resistors R1 and R2.

The control signal CVO is applied on a gate of a PMOSFET (P-channel metal oxide semiconductor field effect transistor) TSR in the voltage driving circuit 130. The current flowing through the PMOSFET TSR is controlled by such a control signal CVO for regulating the output voltage VO at the output node N1. A capacitor C1 is coupled to the output node N1.

In the voltage regulator 100, the output voltage VO is disadvantageously increased if the capacitor C1 is also charged by a reverse current IRV that flows to the output node N1 from an external circuit. Such an increase in the output voltage VO influences a sourcing current flowing through the PMOSFET TSR such that the power supplied by the voltage regulator 100 becomes unstable.

A current I2 flowing though the resistors R1 and R2 is significantly smaller than a charging current I1 flowing into the capacitor C1. Thus, the increase in the output voltage VO by the reverse current IRV cannot be significantly suppressed by the current I2. Furthermore, a current sourcing capacity of the voltage driving circuit 130 is degraded if the resistances of the division resistors R1 and R2 are decreased for increasing the current I2.

Since a digital amplifier or a switching amplifier performs switching for efficiency of amplification, the reverse current is commonly generated in the voltage regulator therein. Unfortunately, the output voltage of such a voltage regulator is increased by the reverse current with degradation of signal-to-noise ratio (SNR) of the digital amplifier and of the THD (third harmonic distortion) characteristics.

### SUMMARY OF THE INVENTION

Accordingly, a voltage regulator of the present invention diverts such external reverse current for generating a stable output voltage.

A voltage regulator according to an aspect of the present invention includes a voltage driving circuit and a current sinking unit. The voltage driving circuit is controlled to maintain an output signal at an output node. The current sinking unit is coupled to the output node for generating a sinking current for diverting an external current to the output node.

In an embodiment of the present invention, the voltage regulator further includes an error amplifier for generating a control signal from the output signal and a reference signal. The voltage driving circuit and the current sinking unit are controlled according to the control signal.

For example, the voltage driving circuit is controlled by the control signal to provide a sourcing current to the output node such that the output signal is maintained at a desired level as indicated by the reference signal.

In another embodiment of the present invention, the external current is a reverse current flowing to the output node from an external source. In that case, the current sinking unit sinks at least a portion of the reverse current away from the output node.

In an example embodiment of the present invention, the voltage driving circuit is a P-channel field effect transistor coupled between a high voltage source and the output node and has a gate controlled according to the control signal. In addition, the current sinking unit is an N-channel field effect transistor coupled between the output node and a ground node and has a gate controlled according to the control signal.

In a further embodiment of the present invention, the voltage regulator also includes a control circuit for generating a first transistor control signal from the control signal as generated by the error amplifier with the first transistor control signal being applied on the gate of the P-channel field effect transistor. The control circuit also generates a second transistor control signal from the control signal with the second transistor control signal being applied on the gate of the N-channel field effect transistor.

In another embodiment of the present invention, the error amplifier is a differential input amplifier. In that case, the voltage regulator further includes a reference voltage generator and a feedback circuit. The reference voltage generator generates the reference signal applied at a negative input of the differential input amplifier. The feedback circuit generates a feedback signal applied at a positive input of the differential input amplifier from the output signal. For example, the feedback circuit includes a resistive voltage divider coupled between the output node and the positive input of the differential input amplifier.

In another embodiment of the present invention, the voltage regulator further includes a capacitor coupled to the output node.

The present invention may be used to particular advantage when the voltage regulator is used within a digital amplifier including a driving circuit for amplifying a pulse width modulation (PWM) signal to generate an amplified PWM signal. In that case, the voltage driving circuit of the voltage regulator maintains an output voltage at the output node coupled to the driving circuit for biasing the driving circuit. In addition, the current sinking unit diverts the reverse current generated by the driving circuit to the output node.

In another embodiment of the present invention, the digital amplifier further includes a low-pass filter for converting the amplified PWM signal to an analog signal. In a further embodiment of the present invention, the driving circuit is a class-D driving circuit.

In this manner, the current sinking unit of the voltage regulator is controlled according to the output signal to generate a sinking current for diverting away at least a portion of the external current to the output node. Thus, the output signal provided by the voltage generator may be maintained to be more stable despite the external current.

### BRIEF DESCRIPTION OF THE DRAWINGS

The above and other features and advantages of the present invention will become more apparent when described in detailed exemplary embodiments thereof with reference to the attached drawings in which:

FIG. 1 is a circuit diagram of a conventional voltage regulator, according to the prior art;

FIG. 2 is a block diagram of a voltage regulator, according to an example embodiment of the present invention;

FIG. 3 is a circuit diagram of the voltage regulator of FIG. 2, according to an example embodiment of the present invention;

FIG. 4 is a block diagram of a digital amplifier with a voltage regulator of FIG. 2, according to an example embodiment of the present invention;

FIG. 5 is shows a simulation result of THD (third harmonic distortion) characteristics in the digital amplifier of FIG. 4; and

FIG. 6 is a flowchart of steps during operation of the voltage regulator of FIG. 2 or 3, according to an example embodiment of the present invention.

The figures referred to herein are drawn for clarity of illustration and are not necessarily drawn to scale. Elements having the same reference number in FIGS. 1, 2, 3, 4, 5, and 6 refer to elements having similar structure and/or function.

### DETAILED DESCRIPTION OF THE INVENTION

Embodiments of the present invention are now described more fully with reference to the accompanying drawings. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout this application.

It will be understood that, although the terms first, second, etc. may be used herein to describe various elements, these elements should not be limited by these terms. These terms are used to distinguish one element from another. For example, a first element could be termed a second element, and similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

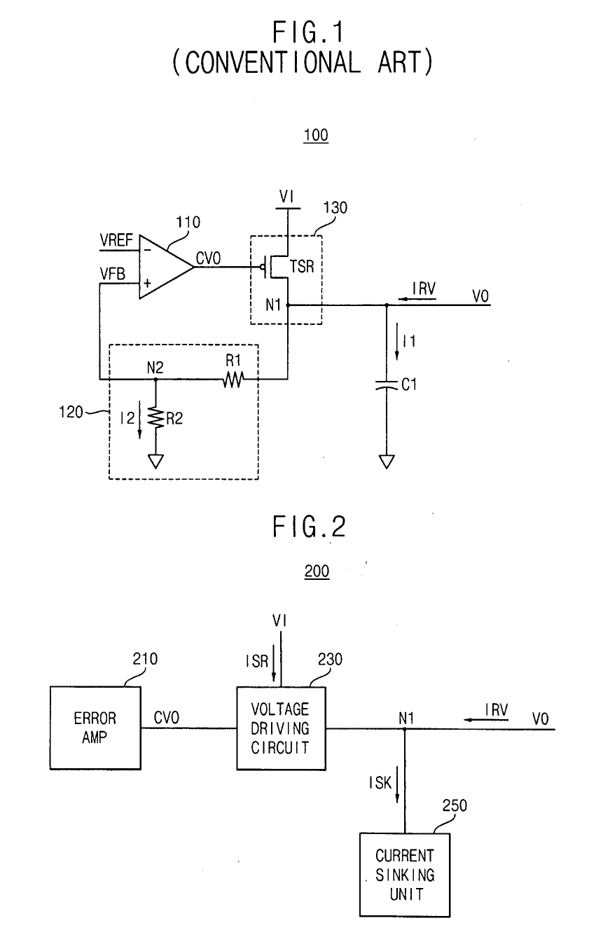

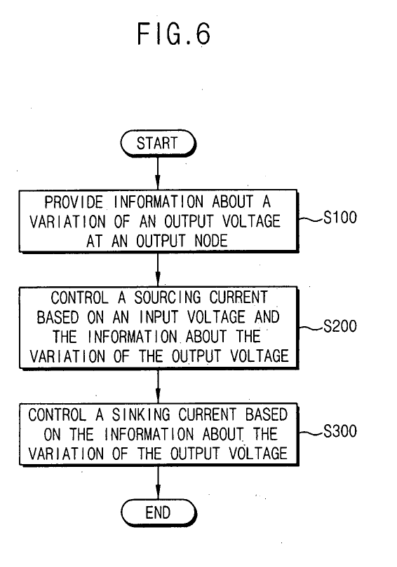

FIG. 2 is a block diagram of a voltage regulator 200 according to an example embodiment of the present invention. Referring to FIG. 2, the voltage regulator 200 includes an error amplifier 210, a voltage driving circuit 230, and a current sinking unit 250. FIG. 6 shows a flow-chart of steps during operation of the voltage regulator 200 of FIG. 6.

The error amplifier 210 generates a voltage control signal CVO including information about variation of an output signal such as an output voltage VO at an output node N1 (step S100 of FIG. 6). The voltage driving circuit 230 is controlled by the voltage control signal CVO to maintain the output voltage VO to a desired level by adjusting a sourcing current ISR (step S200 of FIG. 6). For example, the sourcing current ISR is increased if the output voltage VO at the output node N1 is decreased, and the sourcing current ISR is decreased if the output voltage VO at the output node N1 is increased.

The current sinking unit 250 diverts at least a portion of a reverse current IRV based on the voltage control signal CVO. The reverse current IRV is an external current generated by an external source such as an external circuit outside of the voltage regulator 200. The current sinking unit 250 diverts at least a portion of the reverse current IRV by generating a sinking current ISK that flows away from the output node N1 (step S300 of FIG. 6).

When the reverse current IRV is generated from the external circuit, the voltage regulator 200 promptly sinks the reverse current IRV through the current sinking unit 250 for preventing the output voltage VO from being increased by the reverse current IRV. Accordingly, the voltage regulator 200 generates a stable output voltage.

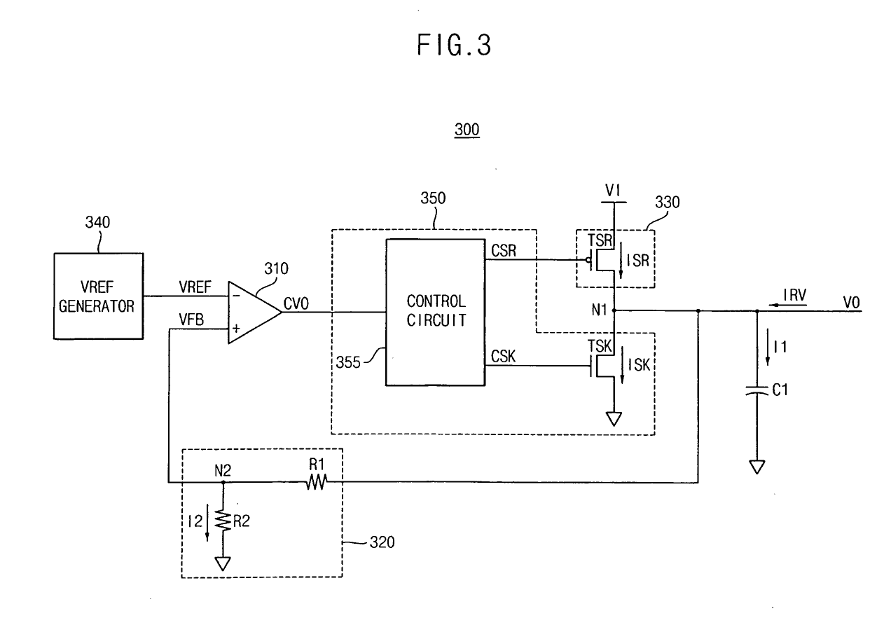

FIG. 3 is a circuit diagram of a voltage regulator 300 such as the voltage regulator 200 of FIG. 2, according to an example embodiment of the present invention. Referring to FIG. 3, the voltage regulator 300 includes a differential input amplifier 310 for the error amplifier 210, a feedback circuit 320, a voltage driving circuit 330, a reference voltage generator 340, and a current sinking unit 350.

The differential input amplifier 310 amplifies a difference between a reference signal such as a reference voltage VREF and a feedback signal such as a feedback voltage VFB to generate the voltage control signal CVO. The reference voltage VREF is generated by the reference voltage generator 340 and is applied at a negative input of the differential input amplifier 310. The feedback voltage VFB is applied at a positive input of the differential input amplifier 310.

The feedback circuit 320 generates the feedback voltage VFB by resistive-dividing the output voltage VO at the output node N1. For example, the feedback circuit 320 includes resistors R1 and R2 coupled in series with the feedback voltage VFB generated at a node N2 between the resistors R1 and R2. The present invention may also be practiced without the feedback circuit 320. In that case, the output voltage VO would be directly applied on the positive input of the differential input amplifier 310.

The reference voltage generator 340 may also be implemented with resistors used as a voltage divider for generating the reference voltage VREF, similar to the feedback circuit 320. In case a more stable reference voltage is desired, the reference voltage generator 340 may be implemented with a band-gap reference voltage circuit. As known to one of ordinary skill in the art, a band-gap reference voltage circuit provides a stable reference voltage that is insensitive to temperature variation.

The voltage driving circuit 330 is biased by a high voltage source that provides an input voltage VI at an input node. The high driving circuit 330 adjusts the sourcing voltage ISR according to the control signal VCO for maintaining the output voltage VO to a desired level as indicated by the reference voltage VREF. For example, the sourcing current ISR is increased if the output voltage VO is decreased, and the sourcing current ISR is decreased if the output voltage VO is increased.

The current sinking unit 350 adjusts a sinking current ISK for diverting at least a portion or all of the reverse current IRV flowing to the output node N1 from the external source. The current sinking unit 350 adjusts the sinking current ISK according to the control signal CVO.

The voltage driving circuit 330 and the current sinking unit 350 adjust the sourcing current ISR and the sinking current ISK, respectively, according directly to the level of the control signal CVO. Alternatively as illustrated in FIG. 3, the voltage driving circuit 330 and the current sinking unit 350 adjust the sourcing current ISR and the sinking current ISK, respectively, from transistor control signals derived from the control signal CVO.

Referring to FIG. 3, the voltage driving circuit 330 is comprised of a PMOSFET (P-channel metal oxide semiconductor field effect transistor) TSR having a source with the input voltage VI applied thereon and having a drain coupled to the output node N1. The current sinking unit 350 includes an NMOSFET (N-channel metal oxide semiconductor field effect transistor) TSK having a source coupled to a ground node and having a drain coupled to the output node N1.

The current sinking unit 350 further includes a control circuit 355 for generating a first transistor control signal CSR and a second transistor control signal CSK from the control signal CVO as generated by the differential input amplifier 310. The first transistor control signal CSR is applied on a gate of the PMOSFET TSR of the voltage driving circuit 330. The second transistor control signal CSK is applied on a gate of the NMOSFET TSK of the current sinking unit 350.

For example, the first and second transistor control signals CSR and CSK are adjusted by the control circuit 350 for complementarily adjusting the sourcing current ISR and the sinking current ISK depending on the control signal CVO. In an example embodiment of the present invention, the control circuit 350 is implemented as a class-AB control circuit such that a bias current flows through the PMOSFET TSR and the NMOSFET TSK.

An amplifier is classified according to an operation of an output stage. In particular, an audio amplifier is classified into class-A, class-B, class-AB, or class-D according to a driving circuit of an output stage. In the class-A output stage, bias voltages are applied to output transistors such that a bias current flows through the output transistors in a mute state. Thus, the class-A output stage disadvantageously has high power dissipation and low efficiency.

The class-B output stage is configured to prevent a bias current flowing in the output transistors in the mute state. However, the class-B output stage has significant crossover distortion when the output signal passes through a reference voltage since the output transistors are turned off.

The class-AB output stage is configured to have a small bias current flowing in the output transistors in the mute state. Thus, the class-AB output stage has lower distortion than the class-B output stage and higher power efficiency than the class-A output stage.

The voltage driving circuit 330 and the current sinking unit 350 are configured similar to the class-AB output stage with a small bias current flowing through the MOSFETs TSR and TSK. Thus when the external reverse current IRV is generated to the output node N1 from the external source, the sinking current ISK through the NMOSFET TSK is promptly increased. In this manner, increase in the output voltage VO by the reverse current IRV is effectively suppressed while maintaining the current sourcing capacity of the voltage driving circuit 330.

The externally generated reverse current IRV is dissipated by the currents I1, I2, and the sinking current ISK. The current I1 flowing into the capacitor C1 increases the output voltage VO by charging the capacitor C1. The current I2 flowing through the division resistors R1 and R2 in the feedback circuit 320 is significantly smaller than the current I1, and thus cannot significantly suppress the increase of the output voltage VO by the reverse current IRV. In addition, the current sourcing capacity of the voltage driving circuit 330 would be disadvantageously reduced if the resistances of the resistors R1 and R2 are decreased to increase the current I2.

Thus according to the present invention, the sinking current ISK is used for diverting the reverse current IRV away from the output node N1 for preventing the output voltage VO from increasing. Thus, the voltage regulator 300 provides a stable output voltage VO despite the externally generated reverse current IRV.

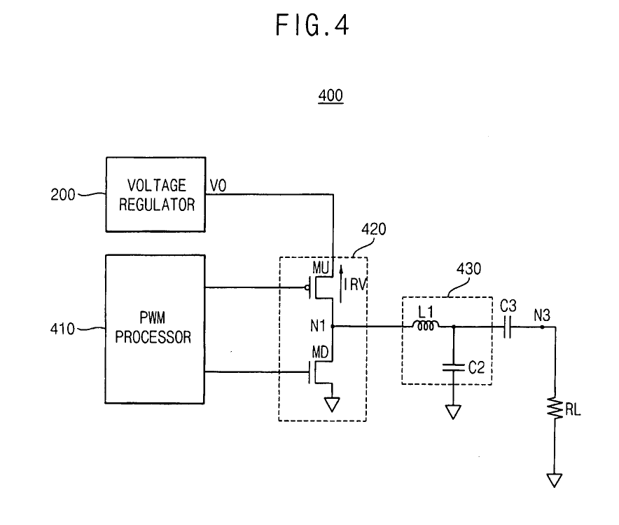

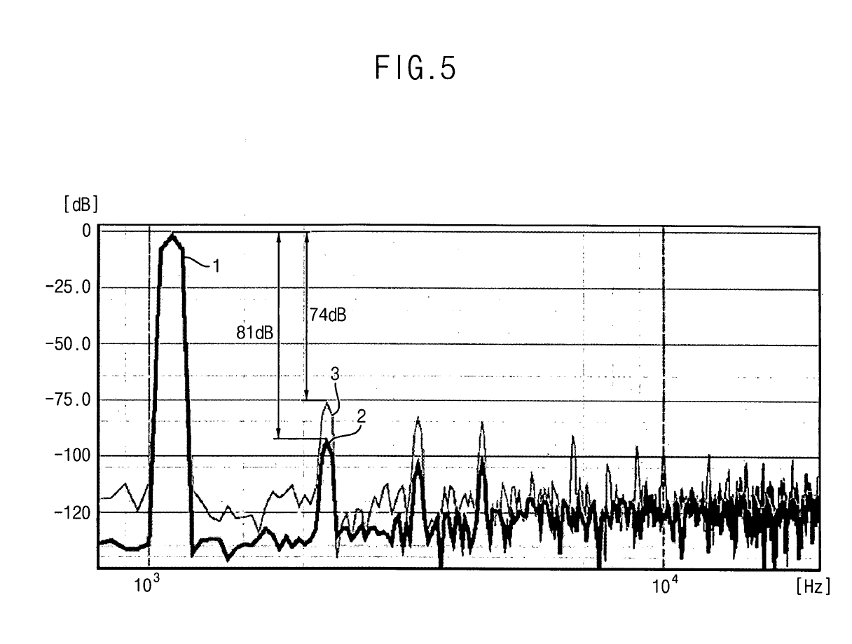

FIG. 4 is a block diagram of a digital amplifier 400 according to an example embodiment of the present invention. Referring to FIG. 4, the digital amplifier 400 includes the voltage regulator 200 of FIG. 2, a pulse width modulation (PWM) processor 410, a class-D driving circuit 420, and a low-pass filter 430.

The voltage regulator 200 in FIG. 2 is implemented similarly as illustrated in FIG. 2 or as the voltage regulator 300 of FIG. 3, according to an embodiment of the present invention. In that case the output node N1 of the voltage regulator 200 is coupled to the class-D driving circuit 420 for biasing the class-D driving circuit 420 with the output voltage VO.

The class-D driving circuit 420 includes a PMOSFET MU and an NMOSFET MD both operating as ON/OFF switches. The class-D driving circuit 420 amplifies a pulse width modulated signal applied to the gates of the transistors MU and MD. A turn-on resistance of the MOSFETs MU and MD is relatively small and thus the class-D driving circuit 420 has a characteristic of high efficiency.

According to the IEC (International Electrotechnical Commission) standard, the class-D amplifier is defined as any amplifier “in which the current in each active device supplying the load is switched from zero to a maximum value by a carrier signal, modulation of which conveys the useful signal.” The audio amplifier including such a class-D output stage or such a class-D driving circuit is referred to as a digital amplifier or a switching amplifier.

As described above in reference to FIGS. 2 and 3, the voltage regulator 200 controls the sourcing current therein to maintain the output voltage VO to a desired level for biasing the class-D driving circuit 420. In addition, the voltage regulator 200 controls the sinking current therein to divert the reverse current IRV generated by the class-D driving circuit 420.

The class-D driving circuit 420 receives the output voltage VO of the voltage regulator 200 as a power supply voltage. The class-D driving circuit 420 includes the PMOSFET MU and the NMOSFET MD operating as ON/OFF switches for amplifying a pulse width modulation (PWM) signal to generate an amplified PWM signal.

The low-pass filter 430 converts the amplified PWM signal from the class-D driving circuit 420 to an analog signal. As illustrated in FIG. 4, the low-pass filter 430 includes an inductor L1 and a capacitor C2 with the characteristics of the low-pass filter 430 being determined by a time constant corresponding to a product of the inductance of the inductor L1 and the capacitance of the capacitor C2.

A decoupling capacitor C3 is included to remove a DC component or an offset of the analog signal generated by the low-pass filter 430. Thus, an analog signal without the DC component is output through an output node N3 of the digital amplifier 400 with an output load RL being coupled between the output node N3 and the ground node. The output load RL may be included in a sound generating device such as a speaker.

The digital amplifier 400 amplifies the PWM signal based on a stable power supply voltage which is the output voltage VO of the voltage regulator 200 and thus generates a sound signal with reduced noise. FIG. 5 illustrates a simulation result of THD (third harmonic distortion) characteristics in the digital amplifier 400 of FIG. 4.

Frequency components of signals are illustrated in FIG. 5 when the digital amplifier 400 operates at a clock of 1 KHz. When an ideal power without noise is supplied, the first harmonic 2 is decreased by 81 dB with respect to an operation wave 1. In case of the digital amplifier 400 including the voltage regulator 200 according to an example embodiment of the present invention, the first harmonic 3 is decreased by 74 dB, which shows a small difference compared with the ideal case of 81 dB. As such, the digital amplifier 400 including the voltage regulator 200, according to an example embodiment of the present invention, has superior harmonic characteristics for providing a sound signal of high quality.

While the present invention has been shown and described with reference to exemplary embodiments thereof, it will be understood by those of ordinary skill in the art that various changes in form and detail may be made herein without departing from the spirit and scope of the present invention, as defined by the following claims.

The present invention is limited only as defined in the following claims and equivalents thereof.

What is claimed is:

1. A voltage regulator comprising:
a voltage driving circuit that is controlled to maintain an output signal at an output node; and
a current sinking unit coupled to the output node for generating a sinking current for diverting an external current to the output node.

2. The voltage regulator of claim 1, further comprising:
an error amplifier for generating a control signal from the output signal and a reference signal,
wherein the voltage driving circuit and the current sinking unit are controlled according to the control signal.

3. The voltage regulator of claim 2, wherein the voltage driving circuit is controlled by the control signal to provide a sourcing current to the output node such that the output signal is maintained at a desired level as indicated by the reference signal.

4. The voltage regulator of claim 3, wherein the external current is a reverse current flowing to the output node from an external source.

5. The voltage regulator of claim 4, wherein the current sinking unit sinks at least a portion of the reverse current away from the output node.

6. The voltage regulator of claim 5, wherein the voltage driving circuit is a P-channel field effect transistor coupled between a high voltage source and the output node and having a gate controlled according to the control signal, and wherein the current sinking unit is an N-channel field effect transistor coupled between the output node and a ground node and having a gate controlled according to the control signal.

7. The voltage regulator of claim 6, further comprising:
a control circuit for generating a first transistor control signal from the control signal as generated by the error amplifier with the first transistor control signal being applied on the gate of the P-channel field effect transistor, and for generating a second transistor control signal from the control signal with the second transistor control signal being applied on the gate of the N-channel field effect transistor.

8. The voltage regulator of claim 2, wherein the error amplifier is a differential input amplifier.

9. The voltage regulator of claim 8, further comprising:
a reference voltage generator for generating the reference signal applied at a negative input of the differential input amplifier.

10. The voltage regulator of claim 9, further comprising:
a feedback circuit for generating a feedback signal applied at a positive input of the differential input amplifier from the output signal.

11. The voltage regulator of claim 10, wherein the feedback circuit includes:
a resistive voltage divider coupled between the output node and the positive input of the differential input amplifier.

12. The voltage regulator of claim 1, further comprising:
a capacitor coupled to the output node.

13. A digital amplifier comprising:
a driving circuit for amplifying a pulse width modulation (PWM) signal to generate an amplified PWM signal; and
a voltage regulator including:
a voltage driving circuit that is controlled to maintain an output voltage at an output node coupled to the driving circuit for biasing the driving circuit; and
a current sinking unit coupled to the output node for generating a sinking current that diverts an external current generated by the driving circuit to the output node.

14. The digital amplifier of claim 13, further comprising:
a low-pass filter for converting the amplified PWM signal to an analog signal.

15. The digital amplifier of claim 13, wherein the driving circuit is a class-D driving circuit.

16. The digital amplifier of claim 13, wherein the voltage regulator further includes:
an error amplifier for generating a control signal from the output voltage and a reference voltage,
wherein the voltage driving circuit and the current sinking unit are controlled according to the control signal.

17. The digital amplifier of claim 16, wherein the voltage driving circuit is controlled by the control signal to provide a sourcing current to the output node such that the output voltage is maintained at a desired level as indicated by the reference voltage, and wherein the external current is a reverse current flowing to the output node from the driving circuit.

18. The digital amplifier of claim 17, wherein the voltage driving circuit is a P-channel field effect transistor coupled between a high voltage source and the output node and having a gate controlled according to the control signal, and wherein the current sinking unit is an N-channel field effect transistor coupled between the output node and a ground node and having a gate controlled according to the control signal.

19. The digital amplifier of claim 16, wherein the error amplifier is a differential input amplifier, and wherein the voltage regulator further includes:
a reference voltage generator for generating the reference voltage applied at a negative input of the differential input amplifier; and
a feedback circuit for generating a feedback voltage applied at a positive input of the differential input amplifier from the output voltage.

20. The digital amplifier of claim 19, wherein the feedback circuit includes:
a resistive voltage divider coupled between the output node and the positive input of the differential input amplifier.
